(19) United States
(12) Patent Application Publication
(10) Pub. No.: US 2003/0224544 A1
(43) Pub. Date: Dec. 4, 2003

(54) Test method

(75) Inventors: Alfred John Prisco, Lansdale, PA (US); Carleton James Barbour, Ambler, PA (US); Yujian You, Lansdale, PA (US); Michael K. Gallagher, Hopkinton, MA (US); Kai Hu, Ambler, PA (US)

Correspondence Address: S. Matthew Cairns, c/o EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 10/310,293

(22) Filed: Dec. 5, 2002

Related U.S. Application Data
(60) Provisional application No. 60/338,444, filed on Dec. 6, 2001.

(51) Int. Cl. H01L 21/31; G01R 31/26; H01L 21/66; H01L 21/469

(52) U.S. Cl. 438/16; 438/17; 438/780; 438/781

(57) ABSTRACT

Methods for determining the extent and nature of porosity in dielectric materials, particularly in thin dielectric films, using electrochemical impedance spectroscopy are disclosed. Such methods are useful in the manufacture of integrated circuits having porous dielectric layers.

### BACKGROUND OF THE INVENTION

This invention relates generally to dielectric materials. In particular, this invention relates to the development of a test method to determine the nature of porosity in dielectric materials, such as dielectric films used in integrated circuit manufacture.

Dielectric materials are used as insulators in a wide variety of electronic devices, such as printed wiring boards, integrated circuits and optoelectronic devices. These materials may be organic, inorganic or a composite of an organic and inorganic material.

As electronic devices become smaller, there is a continuing desire in the electronics industry to increase the circuit density in electronic components, e.g., integrated circuits, circuit boards, multichip modules, chip test devices, and the like without degrading electrical performance, e.g., crosstalk or capacitive coupling, and also to increase the speed of signal propagation in these components. One method of accomplishing these goals is to reduce the dielectric constant of the interlayer, or intermetal, insulating material used in the components. A method for reducing the dielectric constant of such interlayer, or intermetal, insulating material is to incorporate within the insulating film very small, uniformly dispersed pores or voids.

Optoelectronic devices such as waveguides have core and cladding regions. The cladding region typically has a lower index of refraction than the core. One method of providing a cladding material having a lower index of refraction is by making such material porous.

Porous dielectric matrix materials are well known in the art. One known process of making a porous dielectric involves co-polymerizing a thermally labile monomer with a dielectric monomer to form a block copolymer, followed by heating to decompose the thermally labile monomer unit. See, for example, U.S. Pat. No. 5,776,990.

As dimensions shrink in electronic device manufacture, such as in integrated circuit manufacture, there is an increasing need for dielectric materials having lower dielectric constants (“k”). Increasing the extent of pores or voids in the dielectric material is one way to achieve this. For example, U.S. Pat. No. 6,271,273 (You et al.) discloses a process processes for manufacturing an integrated circuit device containing a porous organo polysilica dielectric layer using certain polymeric particles as porogens that do not substantially agglomerate. By using such porogens the formation of large or “killer” pores is greatly reduced or eliminated. This allows for a higher loading of pores in the dielectric material than provided by other methods. See also European Patent Application No. 1 088 848 (Allen et al.) which discloses the use of certain polymeric particles as porogens for a variety of dielectric materials.

The nature of the porosity in such dielectric materials is very important in certain applications. Interconnected pores in the very thin dielectric films used in integrated circuits could easily lead to crosstalk. The extent of porosity in the dielectric material is also important.

In general, the size and nature of porosity is relatively easy to probe in a solid bulk sample. Typical techniques to probe the pore structure and pore dimensions include nitrogen and mercury porosimetry, xenon nuclear magnetic resonance imaging, and ultrasound. Methods of analyzing particles in solutions and adsorption of gases are outlined in Hemnitz, Principles of Colloid and Surface Chemistry, Marcel Dekker, New York, p 489-544. However, all of these techniques are unsuitable when trying to elucidate the nature of a thin dielectric film, such as that on a silicon wafer. In this special case the volume of material is too small relative to the weight and mass of the silicon substrate so that these techniques do not effectively probe the pore structure present in the film. New techniques have been applied to this problem such as PALS or SANS which require the handling of radioactive isotopes or nuclear reactors to generate the positronium ions or neutron particles respectively and therefore are too expensive and complex for use in a commercial laboratory or manufacturing facility.

There is thus a need for an improved method for determining the pore interconnectivity of a dielectric materials, particularly thin dielectric films. Such method would be of particular use in the manufacture of electronic and optoelectronic components, and in particular, as an interlayer, or intermetal, dielectric material for use in the fabrication of integrated circuit.

### SUMMARY OF THE INVENTION

It has been surprisingly found that by using a salt (conductance) bridge to contact the topside of a thin dielectric film the nature of porosity within a dielectric film could be determined using standard electrochemical methods, such as electrochemical impedance spectroscopy. Accordingly, the critical volume loading at which the pore structure in the dielectric material becomes interconnected for a given pore forming material or porogen can be determined.

In a first aspect, the present invention provides a method for determining the nature of pore interconnectivity in a dielectric material comprising the steps of: a) making electrical contact with a dielectric material using a conductive solution; b) applying a potential to the film; and c) measuring a response correlated to the applied potential.

In another aspect, the present invention provides a method for determining the nature of pore interconnectivity in a dielectric material comprising the steps of: a) depositing a conductive solution on a surface of a dielectric material; b) making electrical contact with the conductive solution and the side of the dielectric material opposite to the conductive solution; c) applying a potential to the dielectric material; and d) measuring a response to the applied potential.

In still another aspect, the present invention provides a method of manufacturing an integrated circuit comprising the steps of: a) disposing a dielectric material on an electronic device substrate; b) curing the dielectric material; c) depositing a conductive solution on a surface of a dielectric material; d) making electrical contact with the conductive solution and the side of the dielectric material opposite to the conductive solution; e) applying a potential to the dielectric material; and f) measuring a response to the applied potential.

In a further aspect, the present invention provides an apparatus for manufacturing integrated circuits comprising: a) a means for dispensing a conductive solution on a dielectric material on an electronic device substrate; b) a first electrical contact for contacting the conductive solution; c) a second electrical contact for contacting the dielectric material opposite to the conductive solution; d) means for applying a potential; and e) means for measuring a response to the applied potential.

### BRIEF DESCRIPTION OF THE DRAWINGS

FIG. 1 illustrates a modified Randles circuit.

FIG. 2 illustrates one embodiment of a test cell for determining the pore structure of dielectric materials.

FIG. 3 illustrates a second embodiment of a test cell for determining the pore structure of dielectric materials.

FIG. 4 illustrates a third embodiment of the invention for determining the pore structure of dielectric materials during the manufacture of an electronic device.

### DETAILED DESCRIPTION OF THE INVENTION

As used throughout this specification, the following abbreviations shall have the following meanings, unless the context clearly indicates otherwise: ° C.=degrees centigrade; UV=ultraviolet; nm=nanometer; g=gram; wt %=weight percent; L=liter; mL=milliliter; S/m=Siemens per meter; cm=centimeter; V=volt; mV=millivolt; and M=molar.

“Halo” refers to fluoro, chloro, bromo and iodo. Likewise, “halogenated” refers to fluorinated, chlorinated, brominated and iodinated. The term “(meth)acrylic” includes both acrylic and methacrylic and the term “(meth)acrylate” includes both acrylate and methacrylate. Likewise, the term “(meth)acrylamide” refers to both acrylamide and methacrylamide. “Alkyl” includes straight chain, branched and cyclic alkyl groups. The term “porogen” refers to a pore forming material, that is a polymeric material or particle dispersed in a dielectric material that is subsequently removed to yield pores, voids or free volume in the dielectric material. Thus, the terms “removable porogen,” “removable polymer” and “removable particle” are used interchangeably throughout this specification. The terms “pore,” “void” and “free volume” are used interchangeably throughout this specification. “Cross-linker” and “cross-linking agent” are used interchangeably throughout this specification. “Polymer” refers to polymers and oligomers. The term “polymer” also includes homopolymers and copolymers. The terms “oligomer” and “oligomeric” refer to dimers, trimers, tetramers and the like. “Monomer” refers to any ethylenically or acetylenically unsaturated compound capable of being polymerized. Such monomers may contain one or more double or triple bonds.

The term “B-staged” refers to uncured or pre-polymeric organo polysilica dielectric matrix materials. By “uncured” is meant any organo polysilica material that can be polymerized or cured, such as by condensation, to form higher molecular weight materials, such as coatings or films. Such B-staged material may be monomeric, oligomeric or mixtures thereof. B-staged material is further intended to include mixtures of polymeric material with monomers, oligomers or a mixture of monomers and oligomers.

Unless otherwise noted, all amounts are percent by weight and all ratios are by weight. All numerical ranges are inclusive and combinable in any order, except where it is obvious that such numerical ranges are constrained to add up to 100%.

The nature of pore interconnectivity in a dielectric material is determined according to the present invention by a method comprising the steps of: a) making electrical contact with a dielectric material using a conductive solution; b) applying a potential to the film; c) measuring a response to the applied potential. Typically, a conductive solution is applied to a first or top surface of the dielectric material to be analyzed. The dielectric material may be a self-supporting material, but is typically disposed on a substrate. It is preferred that the substrate is sufficiently electrically conductive to provide for measurement of impedance or current. Particularly suitable substrates are wafers used in integrated circuit manufacture, such as silicon wafers, gallium arsenide wafers, and the like. A first electrical contact is contacted with the conductive solution and a second electrical contact is contacted with the bottom side of the dielectric material (or side of the substrate) opposite to the conductive solution. The first electrical contact functions as the counter electrode and the second electrical contact functions as the working electrode. Such first electrical contact makes contact between the conductive solution and the means for applying the potential. Such second electrical contact makes contact between the underside of the sample to be analyzed and the means for applying the potential.

A voltage (alternating current potential) is then applied to the dielectric material and the change in response to the applied potential, either over time or with reference to an impervious (“non-porous”) dielectric material is measured.

Typically, the response that is measured is current. Such measured response is then used to calculate the impedance, conductance or capacitance of the dielectric material. The nature of pore interconnectivity of the dielectric material is typically determined by comparing the change in the impedance, conductance, capacitance or current with time, as compound to a non-porous (i.e. reference) dielectric material, or both. It is preferred that impedance or conductivity changes are evaluated to determine pore interconnectivity. Also provided by the present invention is a method for determining the nature of pore interconnectivity in a dielectric material comprising the steps of: a) depositing a conductive solution on a surface of a dielectric material; b) making electrical contact with the conductive solution and the side of the dielectric material opposite to the conductive solution; c) applying a potential to the dielectric material; and d) measuring a response to the applied potential.

A wide variety of conductive solutions may be employed in the present invention. Such solutions typically include a salt dissolved in a solvent. The solvent may be water, organic solvent or mixtures thereof. Suitable organic solvents include, but are not limited to, dimethylsulfoxide, acetonitrile, dimethylformamide, alcohols such as methanol and ethanol, and the like. Other suitable solvents are well known to those skilled in the art.

Suitable salts include, but are not limited to: metal halides such as copper (II) chloride, lithium chloride, sodium chloride, potassium chloride, potassium bromide and alkaline earth halides; metal nitrates such as sodium nitrate, lithium nitrate, potassium nitrate and copper nitrate; alkali metal hydroxides such as lithium hydroxide, sodium hydroxide and potassium hydroxide; alkaline earth metal hydroxides; tetraalkylammonium salts such as tetramethylammonium chloride, tetraethylammonium chloride, tetrabutylammonium fluoride and tetramethylammonium hydroxide; metal fluoroborates such as sodium tetrafluoroborate; metal hypochlorites; metal perchlorates such as lithium perchlorate and sodium perchlorate; metal bromates such as potassium bromate and sodium bromate; fluorophosphates such as hexafluoro phosphate; and the like. Preferred salts are alkali metal halides, alkali metal hydroxides, metal perchlorates, tetraalkylammonium salts, metal fluoroborate salts and metal nitrates. The conductive solutions contain sufficient salt to conduct current. Typically, the salt is present in the solution in a concentration of 0.001 to 10 M, preferably 0.01 to 1 M, and more preferably 0.05 to 0.5 M. A particularly useful salt concentration is 0.05 to 0.2 M.

An amount of the conductive solution is applied to the surface of the dielectric material to be analyzed. The amount of conductive solution may vary over a wide range. Typically, the conductive solution is added in an amount sufficient to conduct electricity between the dielectric material and the first or top electrical contact. The amount of conductive solution will depend, in part, upon the dimensions of the first electrical contact used. A larger electrical contact may require more conductive solution. In general, one or more drops of conductive solution is used. The specific amount of conductive solution needed is well within the ability of those skilled in the art.

In an alternate embodiment, a conductive solution vessel may be applied to the surface of the dielectric material and the conductive solution may be added to this vessel. Such vessel typically has an opening at the bottom and an opening at the top. The vessel bottom is in intimate contact with the dielectric material to be analyzed. Alternatively, a seal, such as a rubber or plastic o-ring, may be disposed between the bottom opening of the vessel and the dielectric material. The opening at the top allows for the addition of the conductive solution to the vessel. The opening at the bottom of the vessel allows for intimate contact of the conductive solution with the dielectric material to be analyzed. A wide variety of vessels are suitable, including glass or plastic tubes, glass or plastic ball-cock shaped vessels, and the like. Suitable plastics include polytetrafluoroethylene, polyethylene, polypropylene, poly(meth)acrylics, polycarbonates, polyesters, polyamides, and the like.

A wide variety of electrical contacts may be used in the present invention. Such contacts are conductive and are typically metals, such as platinum, and are well known in the art. Such electrical contacts may take a variety of shapes and have a variety of dimensions. The simplest form of such electrical contacts is a wire. Other electrical contacts include electrodes. The choice of such electrical contacts is well within the ability of those skilled in the art.

In an alternate embodiment, a third or reference electrode may optionally be used in the present invention. Such reference electrode is contacted with the conductive solution and connected to the means for applying a potential. It is preferred that a reference electrode is used.

The electrical contacts are typically connected to any means capable of providing a potential. Typically, a potentiostat or battery is used, but other suitable means for providing a potential difference known to those skilled in the art may be used. The potential is an alternating current and may be applied to the dielectric material in a variety of forms, such as a single frequency small amplitude signal, a multi-frequency signal, and the like. The potential applied is typically small, such as <1 V, preferably <0.1 V, more preferably <0.05 V. Particularly suitable potentials are from about 0.1 to 50 mV, preferably from about 1 to 25 mV, and most preferably about 5 to 20 mV.

The present invention preferably utilizes electrochemical impedance spectroscopy (“EIS”) to determine the nature of the porosity of dielectric materials. Dielectric films typically have a very high impedance. When the film matrix contains open channels, a decrease in impedance is recorded as solvent and ions penetrate the film. When monitored by EIS, these phenomena can evaluate the porosity of the dielectric film.

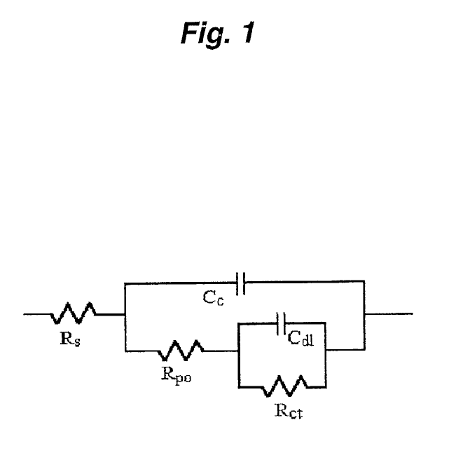

In an EIS experiment, a variable frequency alternating current (“AC”) potential is applied to a system and the current is measured. The response follows Ohm's law, (E=IZ) where the current (“I”) and the impedance (“Z”) are represented by complex numbers. The frequency-independent impedance is related to resistance (“R”) and the frequency-dependent impedance is related to capacitance (“C”). When the data are computer modeled, a modified Randles circuit adequately describes the sample's behavior. A suitable modified Randles circuit is shown in FIG. 1, where R_{ct} is the resistance for the charge transfer and C_{dl} is the double layer capacitance. This model accounts for electrode interfacial reactions (“Rₛ”) as well as the sample's resistance (“Rₚₒ”) and sample's capacitance (“C_{c}”).

This Rₚₒ resistance is an indication of the rate of mass transport of ions into ionically conducting low resistive channels in the film. Values of Rₚₒ are, therefore, related to the film's ionic conductivity, according to the formula

Rₚₒ=ρd=(σ)⁻=(μenz)⁻

where ρ is resistivity, d is electrode separation distance, σ is conductance, μ is mobility, e is the charge on an electron, n is the number of electrons, and z is charge on an ion.

A capacitor is formed when a non-conducting media separates two conducting plates. In the case of a doped silicon wafer, coated with a dielectric, and contacted with a conductive solution, the wafer is one plate, the film is the non-conducting media, and the solution is the second plate. The capacitance of this system is dependent on solvent penetration into the film. In the case of water, the large difference between the dielectric constant of water (78) and that of the non-conducting film (e.g., 1.1-4.1) results in changes to Cc reflecting changes in the dielectric constant of the film. Changes in C_{c} reflect changes in the dielectric constant of the sample according to the formula

C_{c}=(εεₒ/d)A

where ε is the dielectric constant, εₒ is the permittivity of free space, and A is the electrode area.

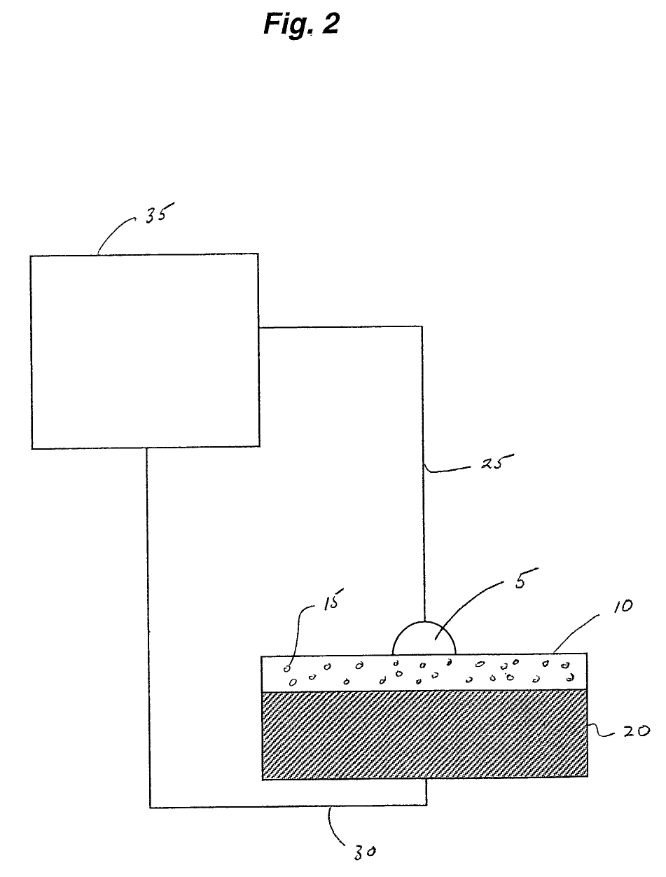

Referring to FIG. 2, the nature of pore interconnectivity of a porous dielectric film is measured by placing a drop of conductive solution 5 on the surface of a porous dielectric film 10 containing pores 15 which is disposed on a substrate 20, such as a conductive silicon wafer. The resistivity (“R”) of such a conductive silicon wafer is typically <0.02 Ohm-cm. A first electrical contact 25 is contacted with the conductive solution 5 and a second electrical contact 30 is contacted with the substrate 20 and disposed opposite to the conductive solution 5. Electrical contacts 25 and 30 are connected to potentiostat 35. A potential is applied to the dielectric film using potentiostat 35 and the response to the applied potential is measured.

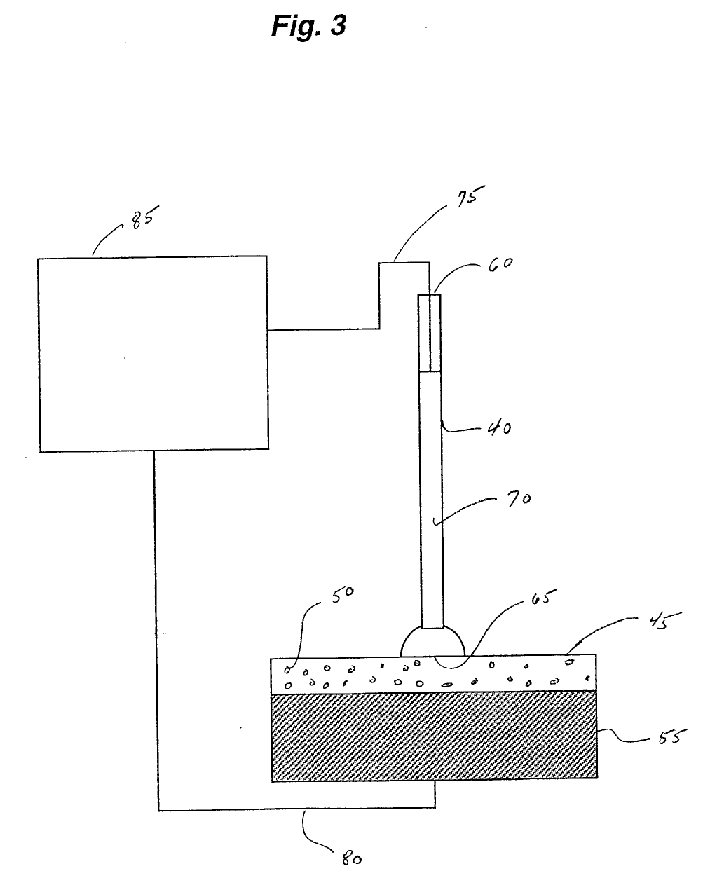

Referring to FIG. 3, the pore interconnectivity of a porous dielectric film is measured by placing a glass ball joint vessel 40 on porous dielectric film 45 having pores 50 and which is disposed on substrate 55, such as a conductive silicon wafer. The resistivity (“R”) of such a conductive silicon wafer is typically <0.02 Ohm-cm. The vessel 40 has a top opening 60 and a bottom opening 65 and is held in place by a fastening means such as a clamp (not shown). The vessel 40 is placed on the porous dielectric film 45 such that the bottom opening 65 is in intimate contact with the porous dielectric film 45. Alternatively, a rubber o-ring (not shown) may be disposed between the bottom opening 65 and the porous dielectric material 45. Conductive solution 70 is added to the vessel 40 through the top opening 60 and is in intimate contact with the porous dielectric film 45 through bottom opening 65. A first electrical contact 75 (platinum) is placed in contact with the conductive solution 70 and a second electrical contact 80 is contacted with the substrate 55 and disposed opposite to the conductive solution 70. A reference electrode (not shown) is also placed in contact with the conductive solution and connected to potentiostat 85. First electrical contact 75 and second electrical contact 80 are connected to potentiostat 85. Potential is applied to the porous dielectric film 45 using potentiostat 85 and the response to the applied potential is measured.

Typically, a computer or microprocessor (not shown in the figures) is used to control the potentiostat and/or measure the capacitance, current and/or change in impedance. Other components that may be included in the present apparatus include a frequency response analyzer, amplifier, impedance meter, and the like. Suitable instruments useful in the present methods are commercially available, such as from Perkin Elmer and Gamry.

A measuring or monitoring system is used to record a response to the applied potential and a number such as impedance, capacitance, conductance or the like is calculated. When calculating impedance, a suitable measuring system is a Solartron 1260 Gain/Phase Analyzer, EG&G Princeton Applied Research (PAR) 273 potentiostat/Galvanostat, and Zplot Impedance Software (available from Scribner Associates) used to measure impedance. Individual data files collected are fitted to a modified Randles circuit, (Zsim Impedance software from Scribner Associates), and their impedance parameters are plotted and compared as a function of time.

The present invention may be used to analyze a variety of dielectric materials to determine the nature and extent of the porosity of such materials. The present invention is particularly suitable for determining whether the pores in such materials are interconnected, i.e. whether the porous dielectric material has an open cell or closed cell structure. In one embodiment, the change in impedance with time is measured or calculated. Typically, the conductive solution is allowed to remain in contact with the dielectric material for a period of time, such as up to 24 hours and the impedance is measured or calculated again. The measured values are then compared to each other or, alternatively, compared to those for a material of the same composition that is non-porous (i.e. a reference material). In general, reference materials have about the same thickness as the dielectric material evaluated. For example, the pore structure in a porous methylsilsesquioxane dielectric film can be determined by measuring or calculating the impedance and comparing the impedance value to that obtained for a non-porous methylsilsesquioxane film.

The difference in the response to the applied potential, such as a difference in impedance, conductance or current, is related to the amount of open pore structure in the porous dielectric material. For example, a lowering of impedance with time indicates that ions form the conductive solution are penetrating the dielectric material, and thus an amount of open pore structure. Differences in conductivity values of less than 1 S/m, as determined using the EIS method, indicate closed cell pore structures. Differences in conductivity values of greater than 1 S/m, as determined using the EIS method, indicate open cell pore structures. By “closed cell” pore structures, it is meant that the pores within the porous dielectric material are substantially non-interconnected, and preferably are not interconnected. By “substantially” non-interconnected it is meant that less than 20%, preferably less than 15%, and more preferably less than 5% of the pores are interconnected.

A wide variety of dielectric materials may suitably be analyzed according to the present invention, including inorganic dielectric materials, organic dielectric materials and inorganic-organic dielectric composites. Inorganic dielectrics are preferred. Suitable dielectric materials include, but are not limited to, inorganic materials such as carbides, oxides, nitrides and oxyfluorides of silicon, boron, or aluminum; silicones; siloxanes, such as silsesquioxanes; silicates; silazanes; and organic matrix materials such as benzocyclobutenes, poly(aryl esters), poly(ether ketones), polycarbonates, polyimides, fluorinated polyimides, polynorbornenes, poly(arylene ethers), polyaromatic hydrocarbons, such as polynaphthalene, polyquinoxalines, poly(perfluorinated hydrocarbons) such as poly(tetrafluoroethylene), and polybenzoxazoles. Suitable dielectric materials are available under the tradenames TEFLON, AVATREL, BCB, SILK, FLARE, AEROGEL, XEROGEL, PARYLENEF, and PARYLENEN. Suitable silsesquioxane compositions include, but are not limited to hydrogen silsesquioxane, alkyl silsesquioxane such as methyl silsesquioxane, aryl silsesquioxane such as phenyl silsesquioxane, and mixtures thereof, such as alkyl/hydrogen, aryl/hydrogen or alkyl/aryl silsesquioxane.

Particularly suitable inorganic dielectric materials are organo polysilica resins. By organo polysilica resin (or organo siloxane) is meant a compound including silicon, carbon, oxygen and hydrogen atoms. Suitable organo polysilica resins are hydrolyzates or partial condensates of one or more silanes of formulae (I) or (II):

RₐSiY₄₋ₐ, (I)

R¹_{b}(R²O)_{3-b}Si(R³)_{c}Si(OR⁴)_{3-d}R⁵_{d} (II)

wherein R is hydrogen, (C₁-C₈)alkyl, aryl, and substituted aryl; Y is any hydrolyzable group; a is an integer of 0 to 2; R¹, R², R⁴ and R⁵ are independently selected from hydrogen, (C₁-C₆)alkyl, aryl, and substituted aryl; R³ is selected from (C₁-C₁₀)alkyl, —(CH₂)ₕ—, —(CH₂)ₕ₁-Eₖ-(CH₂)ₕ₂-, —(CH₂)ₕ-Z, arylene, substituted arylene, and arylene ether; E is selected from oxygen, NR⁶ and Z; Z is selected from aryl and substituted aryl; R⁶ is selected from hydrogen, (C₁-C₆)alkyl, aryl and substituted aryl; b and d are each an integer of 0 to 2; c is an integer of 0 to 6; and h, h1, h2 and k are independently an integer from 1 to 6; provided that at least one of R, R¹, R³ and R⁵ is not hydrogen. “Substituted aryl” and “substituted arylene” refer to an aryl or arylene group having one or more of its hydrogens replaced by another substituent group, such as cyano, hydroxy, mercapto, halo, (C₁-C₆)alkyl, (C₁-C₆)alkoxy, and the like.

It is preferred that R is (C₁-C₄)alkyl or phenyl, and more preferably methyl, ethyl, iso-butyl, tert-butyl or phenyl. Preferably, a is 1. Suitable hydrolyzable groups for Y include, but are not limited to, halo, (C₁-C₆)alkoxy, acyloxy and the like. Preferred hydrolyzable groups are chloro and (C₁-C₂)alkoxy. Suitable organosilanes of formula (I) include, but are not limited to, methyl trimethoxysilane, methyl triethoxysilane, phenyl trimethoxysilane, phenyl triethoxysilane, tolyl trimethoxysilane, tolyl triethoxysilane, propyl tripropoxysilane, iso-propyl triethoxysilane, iso-propyl tripropoxysilane, ethyl trimethoxysilane, ethyl triethoxysilane, iso-butyl triethoxysilane, iso-butyl trimethoxysilane, tert-butyl triethoxysilane, tert-butyl trimethoxysilane, cyclohexyl trimethoxysilane and cyclohexyl triethoxysilane.

Organosilanes of formula (II) preferably include those wherein R¹ and R⁵ are independently (C₁-C₄)alkyl or phenyl. Preferably R¹ and R⁵ are methyl, ethyl, tert-butyl, iso-butyl and phenyl. It is also preferred that b and d are independently 1 or 2. Preferably R³ is (C₁-C₁₀)alkyl, —(CH₂)ₕ—, arylene, arylene ether and —(CH₂)ₕ₁-E-(CH₂)h₂. Suitable compounds of formula (II) include, but are not limited to, those wherein R³ is methylene, ethylene, propylene, butylene, hexylene, norbornylene, cycloheylene, phenylene, phenylene ether, naphthylene and —CH₂—C₆H₄—CH₂—. It is further preferred that c is 1 to 4.

Suitable organosilanes of formula (II) include, but are not limited to, bis(hexamethoxysilyl)methane, bis(hexaethoxysilyl)methane, bis(hexaphenoxysilyl)methane, bis(dimethoxymethylsilyl)methane, bis(diethoxymethyl-silyl)methane, bis(dimethoxyphenylsilyl)methane, bis(diethoxyphenylsilyl)methane, bis(methoxydimethylsilyl)methane, bis(ethoxydimethylsilyl)methane, bis(methoxydiphenylsilyl)methane, bis(ethoxydiphenylsilyl)methane, bis(hexamethoxysilyl)ethane, bis(hexaethoxysilyl)ethane, bis(hexaphenoxysilyl)ethane, bis(dimethoxymethylsilyl) ethane, bis(diethoxymethylsilyl)ethane, bis(dimethoxyphenylsilyl)ethane, bis(diethoxyphenylsilyl)ethane, bis(methoxydimethylsilyl)ethane, bis(ethoxydimethylsilyl)ethane, bis(methoxydiphenylsilyl)ethane, bis(ethoxydiphenylsilyl)ethane, 1,3-bis(hexamethoxysilyl))propane, 1,3-bis(hexaethoxysilyl)propane, 1,3-bis(hexaphenoxysilyl)propane, 1,3-bis(dimethoxymethylsilyl)propane, 1,3-bis(diethoxymethylsilyl)propane, 1,3-bis(dimethoxyphenylsilyl)propane, 1,3-bis(diethoxyphenylsilyl)propane, 1,3-bis(methoxydimehylsilyl)propane, 1,3-bis(ethoxydimethylsilyl)propane, 1,3-bis(methoxydiphenylsilyl)propane, and 1,3-bis(ethoxydiphenylsilyl)propane. Preferred of these are hexamethoxydisilane, hexaethoxydisilane, hexaphenoxydisilane, 1,1,2,2-tetramethoxy-1,2-dimethyldisilane, 1,1,2,2-tetraethoxy-1,2-dimethyldisilane, 1,1,2,2-tetramethoxy-1,2-diphenyldisilane, 1,1,2,2-tetraethoxy-1,2-diphenyldisilane, 1,2-dimethoxy-1,1,2,2-tetramethyldisilane, 1,2-diethoxy-1,1,2,2-tetramethyldisilane, 1,2-dimethoxy-1,1,2,2-tetraphenyldisilane, 1,2-diethoxy-1,1,2,2-tetraphenyldisilane, bis(hexamethoxysilyl)methane, bis(hexaethoxysilyl)methane, bis(dimethoxymethylsilyl)methane, bis(diethoxymethylsilyl)methane, bis(dimethoxyphenylsilyl)methane, bis(diethoxyphenylsilyl)methane, bis(methoxydimethylsilyl)methane, bis(ethoxydimethylsilyl)methane, bis(methoxydiphenylsilyl)methane, and bis(ethoxydiphenylsilyl)methane.

When the B-staged organo polysilica resins comprise a hydrolyzate or partial condensate of organosilanes of formula (II), c may be 0, provided that at least one of R¹ and R⁵ are not hydrogen. In an alternate embodiment, the B-staged organo polysilica resins may comprise a cohydrolyzate or partial cocondensate of organosilanes of both formulae (I) and (II). In such cohydrolyzates or partial cocondensates, c in formula (II) can be 0, provided that at least one of R, R¹ and R⁵ is not hydrogen. Suitable silanes of formula (II) where c is 0 include, but are not limited to, hexamethoxydisilane, hexaethoxydisilane, hexaphenoxydisilane, 1,1,1,2,2-pentamethoxy-2-methyldisilane, 1,1,2,2-pentaethoxy-2-methyldisilane, 1,1,1,2,2-pentamethoxy-2-phenyldisilane, 1,1,1,2,2-pentaethoxy-2-phenyldisilane, 1,1,2,2-tetramethoxy-1,2-dimethyldisilane, 1,1,2,2-tetraethoxy-1,2-dimethyldisilane, 1,1,2,2-tetramethoxy-1,2-diphenyldisilane, 1,1,2,2-tetraethoxy-1,2-diphenyldisilane, 1,1,2-trimethoxy-1,2,2-trimethyldisilane, 1,1,2-triethoxy-1,2,2-trimethyldisilane, 1,1,2-trimethoxy-1,2,2triphenyldisilane, 1,1,2-triethoxy-1,2,2-triphenyldisilane, 1,2-dimethoxy-1,1,2,2-tetramethyldisilane, 1,2-diethoxy-1,1,2,2-tetramethyldisilane, 1,2-dimethoxy-1,1,2,2-tetraphenyldisilane, and 1,2-diethoxy-1,1,2,2-tetra-phenyldisilane.

It will be appreciated that prior to any curing step, the B-staged organo polysilica resins of the present invention may include one or more of hydroxyl or alkoxy end capping or side chain functional groups. Such end capping or side chain functional groups are known to those skilled in the art.

In one embodiment, particularly suitable B-staged organo polysilica resins are hydrolyzates or partial condensates of compounds of formula (I). Such B-staged organo polysilica resins have the formula (III):

((R⁷R⁸SiO)ₑ(R⁹SiO_{1.5})_{f}(R¹⁰SiO_{1.5})_{g}(SiO₂)ᵣ)ₙ (III)

wherein R⁷, R⁸, R⁹ and R¹⁰ are independently selected from hydrogen, (C₁-C₆)alkyl, aryl, and substituted aryl; e, g and r are independently a number from 0 to 1; f is a number from 0.2 to 1; n is integer from about 3 to about 10,000; provided that e+f+g+r=1; and provided that at least one of R⁷, R⁸ and R⁹ is not hydrogen. In the above formula (III), e, f, g and r represent the mole ratios of each component. Such mole ratios can be varied between 0 and about 1. It is preferred that e is from 0 to about 0.8. It is also preferred that g is from 0 to about 0.8. It is further preferred that r is from 0 to about 0.8. In the above formula, n refers to the number of repeat units in the B-staged material. Preferably, n is an integer from about 3 to about 1000.

Suitable organo polysilica resins include, but are not limited to, silsesquioxanes, partially condensed halosilanes or alkoxysilanes such as partially condensed by controlled hydrolysis tetraethoxysilane having number average molecular weight of about 500 to about 20,000, organically modified silicates having the composition RSiO₃, O₃SiRSiO₃, R₂SiO₂ and O₂SiR₃SiO₂ wherein R is an organic substituent, and partially condensed orthosilicates having Si(OR)₄ as the monomer unit. Silsesquioxanes are polymeric silicate materials of the type RSiO_{1.5} where R is an organic substituent. Suitable silsesquioxanes are alkyl silsesquioxanes such as methyl silsesquioxane, ethyl silsesquioxane, propyl silsesquioxane, butyl silsesquioxane and the like; aryl silsesquioxanes such as phenyl silsesquioxane and tolyl silsesquioxane; alkyl/aryl silsesquioxane mixtures such as a mixture of methyl silsesquioxane and phenyl silsesquioxane; and mixtures of alkyl silsesquioxanes such as methyl silsesquioxane and ethyl silsesquioxane. B-staged silsesquioxane materials include homopolymers of silsesquioxanes, copolymers of silsesquioxanes or mixtures thereof. Such materials are generally commercially available or may be prepared by known methods.

It is preferred that the B-staged organo polysilica resin comprises a silsesquioxane, and more preferably methyl silsesquioxane, ethyl silsesquioxane, propyl silsesquioxane, iso-butyl silsesquioxane, tert-butyl silsesquioxane, phenyl silsesquioxane, tolyl silsesquioxane, benzyl silsesquioxane or mixtures thereof. Methyl silsesquioxane, phenyl silsesquioxane and mixtures thereof are particularly suitable. Other useful silsesquioxane mixtures include mixtures of hydrido silsesquioxanes with alkyl, aryl or alkyl/aryl silsesquioxanes. Typically, the silsesquioxanes useful in the present invention are used as oligomeric materials, generally having from about 3 to about 10,000 repeating units.

Particularly suitable organo polysilica B-staged resins are cohydrolyzates or partial condensates of one or more organosilanes of formulae (I) and/or (II) and one or more tetrafunctional silanes having the formula SiY₄, where Y is any hydrolyzable group as defined above. Suitable hydrolyzable groups include, but are not limited to, halo, (C₁-C₆)alkoxy, acyloxy and the like. Preferred hydrolyzable groups are chloro and (C₁-C₂)alkoxy. Suitable tetrafunctional silanes of the formula SiY₄ include, but are not limited to, tetramethoxysilane, tetraethoxysilane, tetrachlorosilane, and the like. Particularly suitable silane mixtures for preparing the cohydrolyzates or partial cocondensates include: methyl triethoxysilane and tetraethoxysilane; methyl trimethoxysilane and tetramethoxysilane; phenyl triethoxysilane and tetraethoxysilane; methyl triethoxysilane and phenyl triethoxysilane and tetraethoxysilane; ethyl triethoxysilane and tetramethoxysilane; and ethyl triethoxysilane and tetraethoxysilane. The ratio of such organosilanes to tetrafunctional silanes is typically from 99:1 to 1:99, preferably from 95:5 to 5:95, more preferably from 90:10 to 10:90, and still more preferably from 80:20 to 20:80.

In a particular embodiment, the B-staged organo polysilica resin is a cohydrolyzate or partial cocondensate of one or more organosilanes of formula (I) and a tetrafunctional silane of formula SiY₄. In another embodiment, the B-staged organo polysilica resin is a cohydrolyzate or partial cocondensate of one or more organosilanes of formula (II) and a tetrafunctional silane of formula SiY₄. In still another embodiment, the B-staged organo polysilica resin is a cohydrolyzate or partial cocondensate of one or more organosilanes of formula (I), one or more silanes of formula (II) and a tetrafunctional silane of formula SiY₄. The B-staged organo polycilica resins of the present invention include a non-hydrolyzed or non-condensed silane of one or more silanes of formulae (I) or (II) with the hydrolayzate or partial condensate of one or more silanes of formulae (I) or (II). In a further embodiement, the B-staged organo polysilica resin comprises a silane of formula (II) and a hydrolyzate of partial condensate of one or more organosilanes of formula (I), and preferably a co-hydrolyzate or partial cocondensate of one or more organosilanes of formula (I) with a tetrafunctional silane of the formula SiY₄ where Y is as defined above. Perferably, such B-staged organo polysilica resin comprises a mixture of one ore more silanes of formula (II) and a cohydrolyzate or partial cocondensate having the formula (RSiO_{1.5}) (SiO₂) where R is as defined above.

When organosilanes of formula (I) are cohydrolyzed or cocondensed with a tetrafunctional silane, it is preferred that the organosilane of formula (I) has the formula RSiY₃, and preferably is selected from methyl trimethoxysilane, methyl triethoxysilane, ethyl trimethoxysilane, ethyl triethoxysilane, phenyl trimethoxysilane, phenyl triethoxysilane and mixtures thereof. It is also preferred that the tetrafunctional silane is selected from tetramethoxysilane and tetraethoxysilane.

Porous dielectric materials may be prepared by a variety of methods. Typically, such porous dielectric materials are prepared by combining porogens with the dielectric materials. The porogens useful in the present invention are any which may be removed providing voids, pores or free volume in the dielectric material chosen and reduce the dielectric constant of such material, particularly those dielectric materials having low dielectric constants (“k”). A low-k dielectric material is any material having a dielectric constant less than about 4.

The removable porogens useful in the present invention are not substantially removed under the processing conditions used to cure the B-staged dielectric material or pattern the dielectric material. The present porogens are removed under conditions which do not substantially degrade or otherwise adversely affect the dielectric material.

A wide variety of removable porogens may be used in the present invention. The removable porogens may be polymers such as polymeric particles, or may be monomers or polymers that are co-polymerized with a dielectric monomer to form a block copolymer having a labile (removable) component. In an alternative embodiment, the porogen may be pre-polymerized with the dielectric monomer to form the B-staged dielectric material which may be monomeric, oligomeric or polymeric. Such pre-polymerized B-staged material is then further cured to form a dielectric layer followed by removal of the porogens to form a porous dielectric layer.

Preferably, the removable porogen is substantially non-aggregated or non-agglomerated in the B-staged dielectric material. Such non-aggregation or non-agglomeration reduces or avoids the problem of killer pore or channel formation in the dielectric matrix. It is preferred that the removable porogen is a porogen particle or is co-polymerized with the dielectric monomer or pre-polymer, and more preferably a porogen particle. It is further preferred that the porogen particle is substantially compatible with the B-staged dielectric matrix material. By “substantially compatible” is meant that a composition of B-staged dielectric material and porogen is slightly cloudy or slightly opaque. Preferably, “substantially compatible” means at least one of a solution of B-staged dielectric material and porogen, a film or layer including a composition of B-staged dielectric material and porogen, a composition including a dielectric matrix material having porogen dispersed therein, and the resulting porous dielectric material after removal of the porogen is slightly cloudy or slightly opaque. To be compatible, the porogen must be soluble or miscible in the B-staged dielectric material, in the solvent used to dissolve the B-staged dielectric material or both. Suitable compatibilized porogens are those disclosed in European Patent Application No. 1 088 848 (Allen et al.) and in U.S. Pat. No. 6,271,273 (You et al.). Other suitable removable particles are those disclosed in U.S. Pat. No. 5,700,844.

Substantially compatibilized porogens, typically have a molecular weight in the range of 10,000 to 1,000,000, preferably 20,000 to 500,000, and more preferably 20,000 to 100,000. The polydispersity of these materials is in the range of 1 to 20, preferably 1.001 to 15, and more preferably 1.001 to 10. It is preferred that such substantially compatibilized porogens are cross-linked. Typically, the amount of cross-linking agent is at least about 1% by weight, based on the weight of the porogen. Up to and including 100% cross-linking agent, based on the weight of the porogen, may be effectively used in the particles of the present invention. It is preferred that the amount of cross-linker is from about 1% to about 80%, and more preferably from about 1% to about 60%. Such cross-linked polymeric particles may have a wide variety of particle sizes, such as from 0.5 to 1,000 nm, preferably 1 to 100 nm and more preferably 2 to 30 nm. The size of the pores in the dielectric films resulting from these cross-linked polymer particles are about the same as the particle size of the polymer particles used.

Suitable block copolymers having labile components useful as removable porogens are those disclosed in U.S. Pat. Nos. 5,776,990 and 6,093,636. Such block copolymers may be prepared, for example, by using as pore forming material highly branched aliphatic esters that have functional groups that are further functionalized with appropriate reactive groups such that the functionalized aliphatic esters are incorporated into, i.e. copolymerized with, the vitrifying polymer matrix. Such block copolymers are suitable for forming porous organic dielectric materials, such as benzocyclobutenes, poly(aryl esters), poly(ether ketones), polycarbonates, polynorbornenes, poly(arylene ethers), polyaromatic hydrocarbons, such as polynaphthalene, polyquinoxalines, poly(perfluorinated hydrocarbons) such as poly(tetrafluoroethylene), polyimides, polybenzoxazoles and polycycloolefins.

To be useful in forming porous dielectric materials, the porogens of the present invention must be at least partially removable under conditions which do not adversely affect the dielectric matrix material, preferably substantially removable, and more preferably completely removable. By “removable” is meant that the porogen depolymerizes or otherwise breaks down into volatile components or fragments which are then removed from, or migrate out of, the dielectric material yielding pores or voids. Any procedures or conditions which at least partially remove the porogen without adversely affecting the dielectric matrix material may be used. It is preferred that the porogen is substantially removed. Typical methods of removal include, but are not limited to: exposure to heat, pressure, vacuum or radiation such as, but not limited to, actinic, IR, microwave, UV, x-ray, gamma ray, alpha particles, neutron beam or electron beam. It will be appreciated that more than one method of removing the porogen or polymer may be used, such as a combination of heat and actinic radiation. It is preferred that the matrix material is exposed to heat or UV light to remove the porogen. It will also be appreciated by those skilled in the art that other methods of porogen removal, such as by atom abstraction, may be employed.

The porogens of the present invention can be thermally removed under vacuum, nitrogen, argon, mixtures of nitrogen and hydrogen, such as forming gas, or other inert or reducing atmosphere. The porogens of the present invention may be removed at any temperature that is higher than the thermal curing temperature and lower than the thermal decomposition temperature of the dielectric matrix material. Typically, the porogens of the present invention may be removed at temperatures in the range of 150° to 450° C. and preferably in the range of 250° to 4250 C. Typically, the porogens of the present invention are removed upon heating for a period of time in the range of 1 to 120 minutes. After removal from the dielectric matrix material, 0 to 20% by weight of the porogen typically remains in the porous dielectric material.

In one embodiment, when a porogen of the present invention is removed by exposure to radiation, the porogen polymer is typically exposed under an inert atmosphere, such as nitrogen, to a radiation source, such as, but not limited to, visible or ultraviolet light. While not intending to be bound by theory, it is believed that porogen fragments form, such as by radical decomposition, and are removed from the matrix material under a flow of inert gas. The energy flux of the radiation must be sufficiently high such that porogen particles are at least partially removed.

The removable porogens are typically added to, dispersed within, dissolved in, or otherwise combined with the B-staged dielectric materials of the present invention in an amount sufficient to provide the desired lowering of the dielectric constant. For example, the porogens may be added to the B-staged dielectric materials in any amount of from about 1 to about 90 wt %, based on the weight of the B-staged dielectric material, preferably from 10 to 80 wt %, more preferably from 10 to 60 wt %, and even more preferably from 15 to 50 wt %.

When the removable porogens are not components of a block copolymer, they may be combined with the B-staged dielectric material by any methods known in the art. Typically, the B-staged material is first dissolved in a suitable high boiling solvent, such as methyl isobutyl ketone, diisobutyl ketone, 2-heptanone, γ-butyrolactone, γ-caprolactone, ethyl lactate propyleneglycol monomethyl ether acetate, propyleneglycol monomethyl ether, diphenyl ether, anisole, n-amyl acetate, n-butyl acetate, cyclohexanone, N-methyl-2-pyrrolidone, N,N′-dimethylpropyleneurea, mesitylene, xylenes, or mixtures thereof to form a solution. The porogens are then dispersed or dissolved within the solution. The resulting composition (e.g. dispersion, suspension or solution) is then deposited on a substrate by methods known in the art, such as spin coating, spray coating or doctor blading, to form a film or layer.

Suitable substrates include, but are not limited to: silicon, silicon on insulator, silicon germanium, silicon dioxide, glass, silicon nitride, ceramics, aluminum, copper, gallium arsenide, plastics, such as polycarbonate, circuit boards, such as FR-4 and polyimide, and hybrid circuit substrates, such as aluminum nitride-alumina. Such substrates may further include thin films deposited thereon, such films including, but not limited to: metal nitrides, metal carbides, metal silicides, metal oxides, and mixtures thereof. In a multilayer integrated circuit device, an underlying layer of insulated, planarized circuit lines can also function as a substrate.

After being deposited on a substrate, the B-staged dielectric material is then at least partially cured, and preferably substantially cured, to form a rigid, cross-linked dielectric matrix material without substantially removing the porogen. Such cured dielectric matrix material is typically a coating or film. The curing of the dielectric material may be by any means known in the art including, but not limited to, heating to induce condensation or e-beam irradiation to facilitate free radical coupling of the oligomer or monomer units. Typically, the B-staged material is cured by heating at an elevated temperature, e.g. either directly or in a step-wise manner, e.g. 200° C. for 2 hours and then ramped up to 300° C. at a rate of 5° C. per minute and held at this temperature for 2 hours. Such curing conditions are known to those skilled in the art and are dependent upon the particular B-staged dielectric material chosen.

Once the B-staged organo polysilica dielectric material is cured, the film is subjected to conditions which remove the porogen without substantially degrading the organo polysilica dielectric matrix material, that is, less than 5% by weight of the dielectric matrix material is lost. Typically, such conditions include exposing the film to heat and/or radiation. It is preferred that the matrix material is exposed to heat or light to remove the porogen. To remove the porogen thermally, the dielectric matrix material can be heated by oven heating or microwave heating. Under typical thermal removal conditions, the polymerized dielectric matrix material is heated to about 350° to 400° C. It will be recognized by those skilled in the art that the particular removal temperature of a thermally labile porogen will vary according to composition of the porogen. Upon removal, the porogen polymer depolymerizes or otherwise breaks down into volatile components or fragments which are then removed from, or migrate out of, the dielectric matrix material yielding pores or voids, which fill up with the carrier gas used in the process. The resulting dielectric material having voids thus has a lower dielectric constant than such material without such voids.

In an alternate embodiment, the present invention is also suitable for determining the size of the pores in the porous dielectric film. This can be done by appropriate selection of salts for use in the conductive solution, e.g. ions of varying sizes can be selected. For example, a salt containing a small ion such as lithium and a salt containing a relatively large ion such as tetrabutylammonium may be used to prepare the conductive solutions. Conductive solutions containing salts of other sizes of ions can also be prepared. Conductive solutions each containing a differently sized ion, can be used in the present methods. Differences in the measured and/or calculated values among these different conductive solutions can be used to probe the size of the pores for a given porous dielectric material.

Also provided by the present invention is a method of manufacturing an integrated circuit comprising the steps of: a) disposing a dielectric material on an electronic device substrate; b) curing the dielectric material; c) depositing a conductive solution on a surface of a dielectric material; d) making electrical contact with the conductive solution and the side of the dielectric material opposite to the conductive solution; e) applying a potential to the dielectric material; and f) measuring a response to the applied potential. Preferably, such dielectric material further comprises porogens. More preferably, such method further comprises the step of removing porogens from the dielectric material prior to the step of depositing the conductive solution on the surface of the dielectric material.

Should interconnectivity problems occur in current integrated manufacturing processes, such problems are not detected until the completed integrated circuits are tested and electrical shorts are found. An advantage of the present invention is that the nature of pore interconnectivity in a porous dielectric sample can be analyzed prior to the completion of the integrated circuit. Thus, if too great an extent of interconnectivity is found, such electronic devices need not be further processed, thus saving resources in the manufacture of integrated circuits. Interconnectivity can be determined at various stages during the manufacture of integrated circuits prior to completion of the integrated circuit, such as prior to the subsequent steps of metallization, chemical-mechanical planarization, further application dielectric material, etc. Preferably, such test is performed after etching or chemical mechanical planarization and the subsequent wet chemical cleaning steps. An advantage of evaluating the integrated circuit substrate at this point in the manufacturing process is that the substrate is already in contact with a liquid. The use of another liquid containing an ionic species (i.e. conductive solution) at this stage does not significantly impact the cycle time of integrated circuit production. In addition, following completion of the evaluation, the conductive solution can be removed by further wet chemical processing in the same equipment.

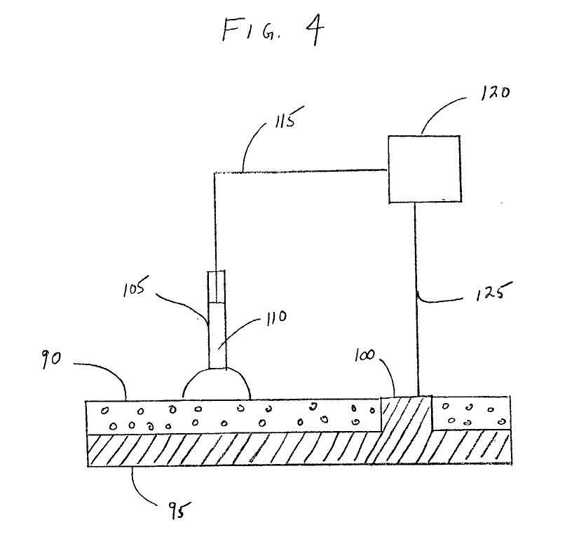

FIG. 4 illustrates one embodiment of determining the interconnectivity of pores in dielectric material during integrated circuit manufacture. A porous dielectric layer 90 is disposed on a copper layer 95. A photoresist (not shown) is applied to the porous dielectric layer 90, imaged, developed and the porous dielectric layer 90 is etched. Subsequent metallization with copper provides a copper pad (or via) 100 which is electrically connected with copper layer 95. Glass ball joint vessel 105 is placed on the porous dielectric layer 90. Conductive solution 110 is added to the glass ball joint vessel 105 and is in intimate contact with porous dielectric layer 90. A first electrical contact 115 is placed in conductive solution 110 and connected to potentiostat 120. A second electrical contact 125 is connected between copper pad 100 and potentiostat 120, thereby making electrical contact with copper layer 95 opposite to conductive solution 110. A reference electrode (not shown) is also placed in contact with conductive solution 110 and connected to potentiostat 120. Potential is applied to the porous dielectric layer 90 using potentiostat 120 and the response to the applied potential is measured.

Further, the present invention provides an apparatus for manufacturing integrated circuits comprising: a) a means for dispensing a conductive solution on a dielectric material on an electronic device substrate; b) a first electrical contact for contacting the conductive solution; c) a second electrical contact for contacting the dielectric material opposite to the conductive solution; d) means for applying a potential; and e) means for measuring a response to the applied potential. Any suitable means may be used for dispensing the conductive solution, such as a spin coater, eye dropper, syringe, pipette or any other suitable liquid transferring means. Such apparatus may be a module within a larger integrated circuit manufacturing apparatus, or may be a separate apparatus.

The following examples are presented to illustrate further various aspects of the present invention, but are not intended to limit the scope of the invention in any aspect.

### EXAMPLE 1

A methyl silsesquioxane (“MeSQ”) sample was prepared by combining Techneglas GR-650F (0.80 g), a methyl silsesquioxane resin, with a porogen having as polymerized units poly(ethylene glycol) methyl ether methacrylate having an average molecular weight of 475/vinyltrimethoxysilane/trimethylolpropane trimethacrylate (80/10/10) in propylene glycol methyl ether acetate (1.33 g, 15 wt %) and propylene glycol methyl ether acetate (1.43 g). The mean particle size of the porogens was 3.5 nm. The sample was deposited on a silicon wafer as a thin coating using spin casting. The thickness (estimated at ˜1.1 μm) of the film was controlled by the duration and spin rate of spread cycle, drying cycle and final spin cycle. The wafer was processed at 150° C. for Iminute followed by heating in a PYREX™ container in an oven to 2000 C under an argon atmosphere. The oxygen content of the container was monitored and was maintained below 5 ppm before heating of the sample. After 30 minutes at 200° C., the furnace was heated at a rate of 10° C. per minute to a temperature of 420° C. and was held for 60 minutes. The decomposition of the polymer particle was accomplished at this temperature without expansion of the polymer. The resulting porous MeSQ film was then heated at 400° C. in air for 1 hour.

The above procedure was repeated using various levels of porogen.

### EXAMPLE 2

The interconnectivity of the porous films from Example 1 were measured by placing a PYREX™ glass ball joint complete with a rubber o-ring against the thin, porous dielectric layer deposited onto a conductive silicon wafer, having a resistivity (“R”) of <0.02 Ohm-cm. The ball joint was held in place by a clamp and then an aqueous 10,000 ppm of copper (as copper nitrate) ICP standard solution in 5% nitric acid was charged into the ball joint. A platinum electrode was placed into the solution and then a reference electrode was also inserted into the solution. The back side of the wafer, i.e. the side opposite the film, was also contacted with an electrode. A measuring or monitoring system was used to record the impedance spectra with a Solartron 1260 Gain/Phase Analyzer, EG&G Princeton Applied Research (PAR) 273 Potentiostat/Galvanostat, and Zplot Impedance Software (available from Scribner Associates). Individual data files were fit to a modified Randles circuit, (Zsim Impedance software from Scribner Associates), and their impedance parameters were plotted and compared as a function of time.

The copper ICP standard solution was allowed to remain in contact with the film for 24 hours and the impedance was measured again. These values were compared to those for a non-porous film. Differences in conductivity values of less than 1 indicate closed cell pore structures. Differences in conductivity values of greater than 1 indicate open cell pore structures.

Experimental Parameters:

| Frequency range | 100 KHz to 0.5 Hz | |
|---|---|---|
| Sine wave amplitude | 10 | mV |
| DC Potential | 1 | volt |
| Points/decade | 5 | |

For each sample film, the impedance value was reduced to the resistance which is then normalized for each of the films by dividing by the film thickness. The results are reported in the Table.

TABLE

| Porogen Loading (%) | Conductivity (S/m) | Interconnectivity |
|---|---|---|
| 0 | 0.017 | Close Cell |
| 20 | 0.214 | Close Cell |
| 22 | 0.205 | Close Cell |
| 24 | 0.159 | Close Cell |
| 26 | 0.298 | Close Cell |
| 28 | 0.136 | Close Cell |
| 30 | 0.543 | Close Cell |
| 35 | 0.439 | Close Cell |
| 40 | 1.771 | Open Cell |

From these data, it can be seen that when a 3.5 nm particle is used, closed cell pore structures having between 35 and 40% porosity can be obtained.

What is claimed is:

1. A method for determining the nature of pore interconnectivity in a dielectric material comprising the steps of: a) depositing a conductive solution on a surface of a dielectric material; b) making electrical contact with the conductive solution and the side of the dielectric material opposite to the conductive solution; c) applying a potential to the dielectric material; and d) measuring a response to the applied potential.

2. The method of claim 1 wherein the dielectric material is porous.

3. The method of claim 1 wherein the dielectric material is selected from the group consisting of silicon carbides, silicon oxides, silicon nitrides, silicon oxyfluorides, boron carbides, boron oxides, boron nitrides, boron oxyfluorides, aluminum carbides, aluminum oxides, aluminum nitrides, aluminum oxyfluorides, silicones, siloxanes, silicates, silazanes, benzocyclobutenes, poly(aryl esters), poly(ether ketones), polycarbonates, polyimides, fluorinated polyimides, polynorbornenes, poly(arylene ethers), polyaromatic hydrocarbons, polyquinoxalines, poly(perfluorinated hydrocarbons), and polybenzoxazoles.

4. The method of claim 1 wherein the dielectric material comprises an organo polysilica resin.

5. A method of manufacturing an integrated circuit comprising the steps of: a) disposing a dielectric material on an electronic device substrate; b) curing the dielectric material; c) depositing a conductive solution on a surface of a dielectric material; d) making electrical contact with the conductive solution and the side of the dielectric material opposite to the conductive solution; e) applying a potential to the dielectric material; and f) measuring the impedance, capacitance or current.

6. The method of claim 5 wherein the dielectric material in step a) comprises porogens.

7. The method of claim 6 further comprising the step of removing the porogens from the dielectric material prior to the step of depositing the conductive solution on the surface of the dielectric material.

8. The method of claim 5 wherein the dielectric material comprises an organo polysilica resin.

9. The method of claim 8 wherein the organo polysilica resin comprises hydrolyzates or partial condensates of one or more silanes of formulae (I) or (II):
RₐSiY₄₋ₐ (I)
R¹_{b}(R²O)_{3-b}Si(R³)_{c}Si(OR⁴)_{3-d}R⁵d (II)
wherein R is hydrogen, (C₁-C₈)alkyl, aryl, and substituted aryl; Y is any hydrolyzable group; a is an integer of 0 to 2; R¹, R², R⁴ and R⁵ are independently selected from hydrogen, (C₁-C₆)alkyl, aryl, and substituted aryl; R³ is selected from (C₁-C₁₀)alkyl, —(CH₂)ₕ—, —(CH₂)ₕ₁-Eₖ-(CH₂)ₕ₂—, —(CH₂)ₕ-Z, arylene, substituted arylene, and arylene ether; E is selected from oxygen, NR⁶ and Z; Z is selected from aryl and substituted aryl; R⁶ is selected from hydrogen, (C₁-C₆)alkyl, aryl and substituted aryl; b and d are each an integer of 0 to 2; c is an integer of 0 to 6; and h, h1, h2 and k are independently an integer from 1 to 6; provided that at least one of R, R¹, R³ and R⁵ is not hydrogen.

10. The method of claim 9 wherein the organo polysilica resin comprises a compound of formula (III):
((R⁷R⁸SiO)_{c}(R⁹SiO_{1.5})_{f}(R¹⁰SiO_{1.5})_{g}(SiO₂)ᵣ)ₙ (III)
wherein R⁷,R⁸,R⁹ and R¹⁰ are independently selected from hydrogen, (C₁-C₆)alkyl, aryl, and substituted aryl; e, g and r are independently a number from 0 to 1; f is a number from 0.2 to 1; n is integer from about 3 to about 10,000; provided that e+f+g+r=1; and provided that at least one of R⁷, R⁸ and R⁹ is not hydrogen.

11. An apparatus for manufacturing integrated circuits comprising: a) a means for dispensing a conductive solution on a dielectric material on an electronic device substrate; b) a first electrical contact for contacting the conductive solution; c) a second electrical contact for contacting the dielectric material opposite to the conductive solution; d) means for applying a potential; and e) means for measuring a response to the applied potential.
